(19) United States
(12) Patent Application Publication
(10) Pub. No.: US 2007/0216887 A1
(43) Pub. Date: Sep. 20, 2007

(54) Illumination System for a Microlithographic Projection Exposure Apparatus

(75) Inventors: Wolfgang Singer, Aalen (DE); Johannes Wangler, Koenigsbronn (DE)

Correspondence Address: FISH & RICHARDSON PC, P.O. BOX 1022, MINNEAPOLIS, MN, 55440-1022, US

(73) Assignee: CARL ZEISS SMT AG, Oberkochen (DE)

(21) Appl. No.: 11/568,204

(22) PCT Filed: Apr. 23, 2004
(86) PCT No.: PCT/EP04/04304

§ 371 Date: Jan. 31, 2007

(51) Int. Cl. G03F 7/20

(52) U.S. Cl. 355/67

(57) ABSTRACT

An illumination system for a microlithographic projection exposure apparatus comprises a light source, a first optical unit having an exit pupil, an optical raster element positioned in or in close proximity to the exit pupil of the first optical unit and a field plane that is conjugated to the exit pupil of the first optical unit by Fourier transformation. The illumination system further comprises a second optical unit imaging the field plane into an image plane and having at its object side a homocentric entrance pupil that at least substantially coincides with the exit pupil of the first optical unit. This allows to dispense with a condenser lens that is usually required for conjugating the exit pupil to the field plane.

### BACKGROUND OF THE INVENTION

1. Field of the Invention

The invention relates generally to illumination systems for microlithographic projection exposure apparatus. More particularly, the invention relates to illumination systems comprising an optical raster element that is positioned in a pupil plane and modifies the size and geometry of an illuminated field on a reticle.

2. Description of Related Art

Microlithography (also called photolithography) is a technology for the fabrication of integrated circuits, liquid crystal displays and other microstructured devices. More particularly, the process of microlithography, in conjunction with the process of etching, is used to pattern features in thin film stacks that have been formed on a substrate, for example a silicon wafer. At each layer of the fabrication, the wafer is first coated with a photoresist which is a material that is sensitive to radiation, such as deep ultraviolet (DUV) light. Next, the wafer with the photoresist on top is exposed to projection light through a reticle (also referred to as a mask) in a projection exposure apparatus, such as a step-and-scan tool. The reticle contains a circuit pattern to be projected onto the photoresist. After exposure the photoresist is developed to produce an image corresponding to the circuit pattern contained in the reticle. Then an etch process transfers the circuit pattern into the thin film stacks on the wafer. Finally, the photo-resist is removed.

A projection exposure apparatus typically includes an illumination system, a projection lens and a wafer alignment stage for aligning the wafer coated with the photo-resist. The illumination system illuminates a region of the reticle with an illumination field that may have the shape of an elongated rectangular slit. As the technology for manufacturing microstructured devices advances, there are ever increasing demands also on the illumination system. For example, there is a need to illuminate the reticle with an illumination field having uniform irradiance.

From U.S. Pat. No. 6,295,443 an illumination system is known in which a first optical raster element is positioned in a first plane that is conjugated by Fourier transformation to an exit pupil of an optical unit. A second optical raster element is positioned in the exit pupil. As a result of this arrangement, the first optical raster element determines the intensity distribution in the exit pupil plane and therefore modifies the angular distribution of light in a subsequent reticle plane. At the same time the geometrical optical flux of the projection light is increased. The second optical raster element modifies the size and geometry of the illuminated field on the reticle and also increases the geometrical optical flux of the projection light bundle. Zoom optics and axicon elements within the optical unit allow to modify the intensity distribution in the pupil plane and therefore the angular distribution of the projection light bundle.

In order to achieve a uniform intensity distribution in the reticle plane, the illumination system of U.S. Pat. No. 6,295,443 further comprises a glass mixing rod having an entrance facet that is positioned in an intermediate field plane. This field plane is conjugated to the exit pupil plane of the optical unit by means of a condenser lens that usually comprises several single optical elements. The glass mixing rod requires a telecentric condenser lens, i.e. a lens having its exit pupil approximately in the infinity so that all principle rays traverse the exit pupil substantially in parallel.

However, it has been found out that illuminating the reticle with projection light having a carefully selected polarization state may considerably improve the imaging of the reticle onto the photoresist. From that point of view, the use of a glass mixing rod is disadvantageous because it destroys the polarization state of the projection light to a large extent.

For that reason future illumination systems will probably do not comprise light mixing elements such as glass rods that destroy the polarization state. However, this requires that other means are found for achieving the desired uniform irradiance in the reticle plane. One approach to solve this problem is to use an adjustable stop device as is disclosed in EP 0 952 491 A2.

The omission of a glass mixing rod allows to redesign illumination systems to a certain extent. The present invention is concerned with this aspect of future illumination systems.

### SUMMARY OF THE INVENTION

In view of the above it is an object of the present invention to provide an illumination system that requires less optical elements and in particular less lenses.

This object is solved, according to a first aspect of the invention, by an illumination system for a microlithographic projection exposure apparatus comprising:
a) a light source,
b) a first optical unit having an exit pupil,
c) an optical raster element positioned in or in close proximity to the exit pupil of the first optical unit,
d) a field plane that is conjugated to the exit pupil of the first optical unit by Fourier transformation, and
e) a second optical unit imaging the field plane into an image plane and having at its object side a homocentric entrance pupil that at least substantially coincides with the exit pupil of the first optical unit.

The invention is based on the idea that a condenser lens that is usually required for establishing a Fourier transform relationship between an exit pupil plane of the first optical unit and a subsequent field plane may be omitted if the refractive power necessary to establish this relationship is shifted to existing optical units, namely the first optical unit and/or the second optical unit. This results in an illumination system in which the second optical unit is not telecentric at its entrance side. Instead, the field plane in which usually a field stop is positioned is illuminated by a homocentric entrance pupil that coincides with the exit pupil of the first optical unit.

The invention therefore allows to dispense with a number of lenses or other optical elements by shifting refractive power into existing neighboring optical units.

A further optical raster element may be positioned in or in close proximity to a plane that is conjugated to the exit pupil plane by the first optical unit. This optical raster element will then manipulate the intensity distribution in the exit pupil plane and thus the angular distribution of the projection light bundle that impinges on the reticle. To the same end, the first optical unit may comprise at least one pupil forming element, for example an optical zoom unit or a pair of axicon elements, that modifies the intensity distribution in the exit pupil.

According to another advantageous embodiment the first optical unit is a collimator, i.e. it produces collimated light. A third optical unit having a positive refractive power is positioned between the optical raster element and the second optical unit. As a result, the optical raster element in the exit pupil is exposed to collimated light which is advantageous for various reasons. The third optical unit is required for conjugating the exit pupil and the subsequent field plane.

An optical raster element may be any optical element that allows to increase the optical geometrical flux of the optical system. Examples for optical raster elements are diffractive optical elements or micro-lens arrays.

According to a second aspect of the invention, an illumination system for a microlithographic projection exposure apparatus comprises:
a) a light source,
b) an optical unit having an exit pupil,
c) a first optical raster element positioned in a plane behind the optical unit in a converging path of rays,
d) a second optical raster element positioned in or in close proximity to an exit pupil of the optical unit, wherein the interspace between the first optical raster element and the second optical raster element is free of optical elements having refractive power.

The concept of shifting refractive power, which is required for establishing a Fourier transform relationship between two conjugated planes, to neighboring optical units is used here to remove all refractive power from the interspace between the two optical raster elements.

### BRIEF DESCRIPTION OF THE DRAWINGS

Preferred embodiments of the invention are described in detail below with reference to the drawings in which

FIG. 1 shows a meridional section through an illumination system according to a first embodiment of the present invention;

FIG. 2 shows a meridional section through an illumination system according to a second embodiment of the present invention in which additional optical elements are provided for manipulating the intensity distribution in the exit pupil;

FIG. 3 shows a meridional section through an illumination system according to a third embodiment of the present invention in which there are no optical elements having refractive power between two optical raster elements.

### DESCRIPTION OF PREFERRED EMBODIMENTS

### First Embodiment

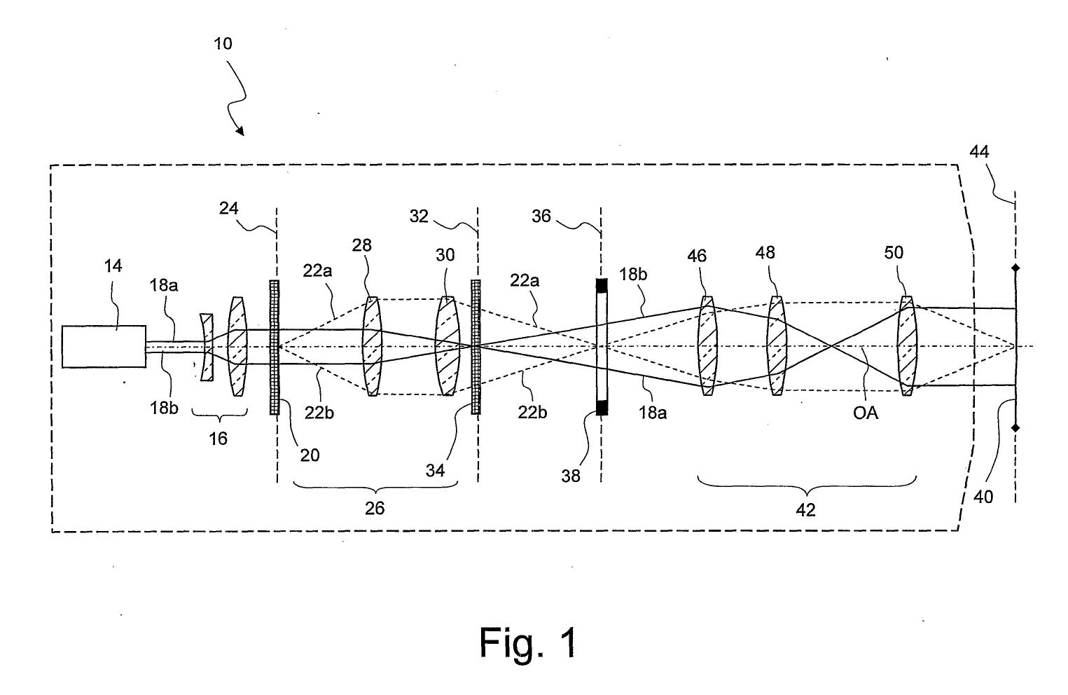

FIG. 1 shows a meridional section of an illumination system according to a first embodiment of the present invention that is to be used in a projection exposure apparatus. For the sake of clarity, the illustration shown in FIG. 1 is considerably simplified and not to scale. This particularly implies that different optical units are represented by very few optical elements only. In reality, these units may comprise significantly more lenses and other optical elements.

The illumination system, which is denoted in its entirety by 10, comprises a light source that is, in the embodiment shown, realized as an excimer laser 14. The excimer laser 14 emits projection light that has a wavelength in the deep ultraviolet (DUV) spectral range, for example 193 nm or 157 nm.

The projection light bundle emitted by the excimer laser 14 enters a beam expansion unit 16 in which the diameter of the projection light bundle is expanded. In FIG. 1 this expansion is represented by rays 18a, 18b of the light bundle. After traversing the beam expansion unit 16 the projection light bundle impinges on a first optical raster element which is, in the embodiment shown, a diffractive optical element 20. The first diffractive optical element 20 comprises one or more diffraction gratings that deflect each impinging ray such that a divergence is introduced. In FIG. 1 this is schematically represented for an axial ray that is split into two diverging rays 22a, 22b. The first diffractive optical element 20 thus modifies the angular distribution of the projection light bundle and also enlarges its geometrical optical flux.

The first diffractive optical element 20 can also be replaced by any other kind of optical raster element, for example a micro-lens array in which the micro-lenses are formed by Fresnel zone plates. Other examples for optical raster elements that are suitable for this purpose are given in U.S. Pat. No. 6,285,443 that has already been mentioned at the outset and is incorporated herein by reference.

The first diffractive optical element 20 is positioned in a front focal plane 24 of a first optical unit 26 that is represented in FIG. 1 by two positive lenses 28, 30. Reference numeral 32 denotes an exit pupil plane of the first optical unit 26. For the sake of simplicity it has been assumed that the rays 18a, 18b have not been deflected by the first diffractive optical element 20. These rays 18a, 18b shall indicate principal rays within the illumination system 10 so that they cross the optical axis OA of the illumination system 10 in the pupil plane 32.

A second diffractive optical element 34 is positioned in the exit pupil plane 32 of the first optical unit 26. The second diffractive optical element 34 once more introduces a divergence for each point and thus enlarges the geometrical optical flux of the projection light bundle a second time. Again, the diffractive optical element 34 may be any kind of optical raster element in the sense as mentioned above. For the sake of simplicity it has been assumed here as well that the rays 22a, 22b and the principal rays 18a, 18b shown right to the second diffractive optical element 34 have not been deflected by the latter.

In a back focal plane 36 of the first optical unit 26 a reticle masking (REMA) unit 38 is positioned. The reticle masking unit 38 comprises two pairs of opposing blades. These blades form a field stop that determines the geometry of the illuminated field on a reticle 40 through which the projection light bundle finally passes. Two this end a second optical unit 42 is provided that comprises three lenses 46, 48, 50 and has an image plane 44 in which the reticle 40 is positioned during the exposure. An object plane of the second optical unit 42 coincides with the back focal plane 36 of the first optical unit 26 so that the reticle masking unit 38 is imaged onto the reticle 40.

The second optical unit 42 has a homocentric entrance pupil which coincides with the exit pupil 32 of the first optical unit 26. Thus there is no condenser lens being telecentric at its image side and used in order to establish a Fourier transform relationship between the conjugated exit pupil plane 32 and a subsequent field plane.

Instead, lenses 30 and 46 are provided within the first optical unit 26 and the second optical unit 42, respectively, that establish said Fourier relationship between the conjugated planes. It has to be noted, however, that in real illumination systems, which usually comprise significantly more lenses than illustrated in FIG. 1 for the sake of simplicity, the omission of a condenser lens will not require more, but less optical elements altogether. This is due to the fact that the refractive power introduced by the “additional” lenses 30 and 46 may also be shifted to already existing lenses. As a consequence, the omission of a condenser lens between the conjugated planes 32 and 36 will in most cases only require a redesign of refractive surfaces in the optical units 26 and 42.

### Second Embodiment

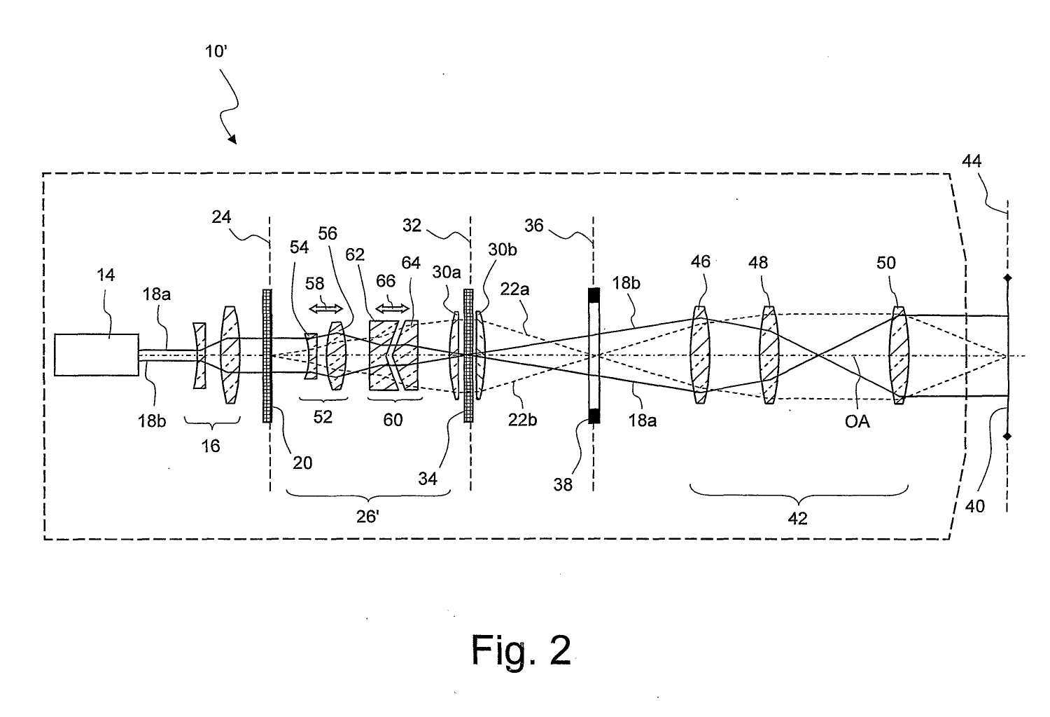

FIG. 2 shows an illumination system 10′ in a meridional section similar to FIG. 1 according to a second embodiment of the invention. The illumination system 10′ differs from the illumination system 10 shown in FIG. 1 in that a first optical unit 26′ further comprises a zoom lens group 52 which is schematically represented by two lenses 54, 56. At least one of these lenses 54, 56 can be shifted along the optical axis OA as is indicated by a double arrow 58. The first optical unit 26′ further comprises an axicon group 60 which consists of two axicon elements 62 and 64. At least one of the axicon elements 62, 64 can be shifted along the optical axis OA as is indicated by a double arrow 66.

The zoom group 52 and the axicon group 60 allow to manipulate the intensity distribution in the exit pupil plane 32 and thus the angular distribution of the projection light that impinges on the reticle 40. Since zoom and axicon groups of this kind are known in the art as such, the groups 52 and 60 will not be explained in further detail.

The illumination system 10′ shown in FIG. 2 further differs from the illumination system 10 shown in FIG. 1 in that the lens 30, which together with lens 34 establishes the Fourier transform relationship between the conjugated planes 32 and 36, is split into two single lenses 30a and 30b. The lens 30b is positioned between the conjugated planes 32 and 36 in such way that between the two lenses 30a, 30b the projection light bundle is collimated. This is advantageous because the second diffractive optical element 34 is then exposed to a collimated projection light bundle which results in a more even and better controllable angular distribution generated by the second diffractive optical element 34.

From the second embodiment shown in FIG. 2 it becomes clear that the omission of a condenser lens does not necessarily imply that there are no optical elements having refractive power between the exit pupil plane 32 and the back focal plane 36 of the first optical unit 26.

### Third Embodiment

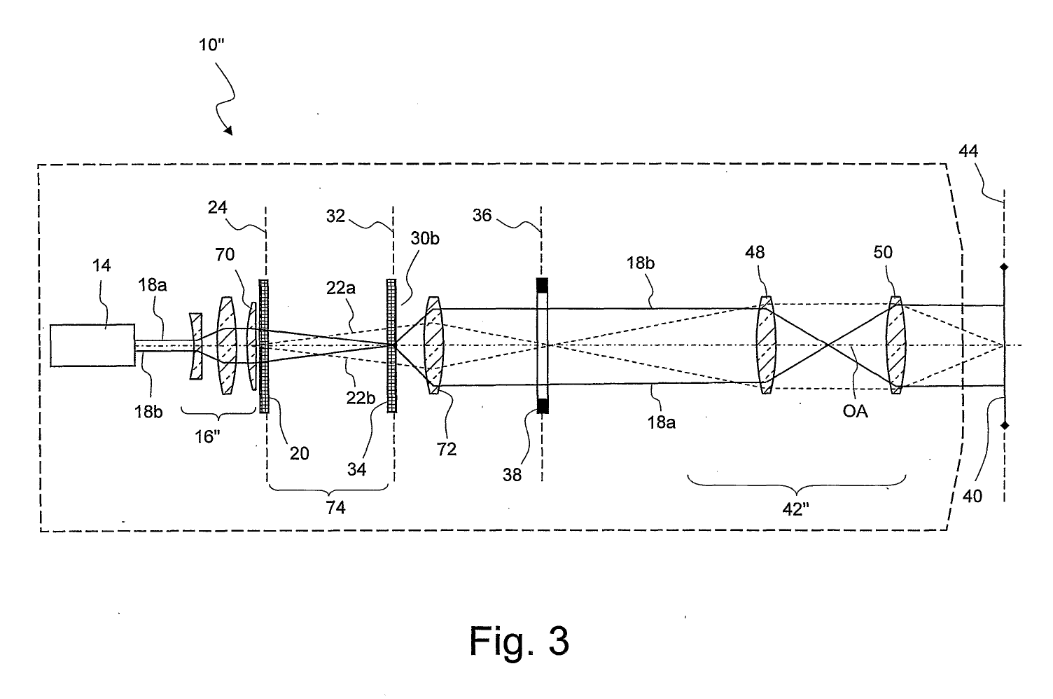

FIG. 3 shows an illumination system 101′ in a meridional section similar to FIGS. 1 and 2 according to a third embodiment of the invention. The illumination system 10′ differs from the illumination system 10 shown in FIG. 1 in that the beam expansion unit, denoted here by 16″, has additional refractive power. This is indicated in FIG. 3 by an additional positive lens 70. As a result, the first diffractive optical element 20 is positioned in a converging path of rays 18a, 18b. In contrast to the embodiments shown in FIGS. 1 and 2, a condenser lens 72 is provided that conjugates the pupil plane 32 of the beam expansion unit 16″ to the back focal plane 36. Due to the condenser lens 72, the additional lens 46 of the second optical unit 42 according to the embodiments shown in FIGS. 1 and 2 can be dispensed with. The second optical unit 42′ shown in FIG. 3 thus has a telecentric entrance pupil.

The concept of shifting refractive power required for establishing a Fourier transform relationship between two conjugated planes is used here to shift all refractive optical power from the first optical unit 26 (as present in the first and second embodiment) to the beam expansion unit 16 and the condenser lens 72. As a result, the interspace 64 between the two diffractive optical elements 20, 34 is completely free of any optical elements having refractive power. Also in this embodiment this will entail a significant reduction of the number of refractive surfaces required to establish a Fourier transform relationship between the front focal plane 24 and the exit pupil plane 32.

This embodiment is particularly advantageous if no manipulation of the intensity distribution in the exit pupil plane 32 by zoom and/or axicon groups is required.

This may be the case, for example, if optical elements can be positioned in the exit pupil plane 32 that allow to modify the intensity distribution to the required extent.

1. An illumination system for a microlithographic projection exposure apparatus, comprising:
a) a light source,
b) a first optical unit having an exit pupil,
c) an optical raster element positioned in or in close proximity to the exit pupil of the first optical unit,
d) a field plane that is conjugated to the exit pupil of the first optical unit by Fourier transformation, and
e) a second optical unit which images the field plane onto an image plane, and has
f) the second optical unit has at its object side a homocentric entrance pupil that at least substantially coincides with the exit pupil of the first optical unit.

2. The illumination system according to of claim 1, comprising a further optical raster element positioned in or in close proximity to a plane that is conjugated to the exit pupil by the first optical unit.

3. The illumination system of claim 1, wherein the first optical unit comprises at least one pupil forming element that modifies an intensity distribution in the exit pupil.

4. The illumination system according to of claim 3, wherein the pupil forming element comprises an optical zoom unit.

5. The illumination system of claim 3, wherein the pupil forming element comprises a pair of axicon elements.

6. The illumination system of claim 1, wherein the first optical unit is a collimator, and wherein a third optical unit having a positive refractive power is positioned between the optical raster element and the second optical unit.

7. The illumination system according to any of the of claim 1, comprising a field stop that is positioned in or in close proximity to the field plane.

8. The illumination system according to any of the of claim 1, wherein the optical raster element is a diffractive optical element or micro-lens array.

9. An illumination system for a microlithographic projection exposure apparatus, comprising:
a) a light source,
b) a first optical unit having an exit pupil,
c) a field plane that is conjugated to the exit pupil of the first optical unit by Fourier transformation,
wherein an interspace formed between the exit pupil and the field plane is free of optical elements having refractive power.

10. The illumination system according to of claim 9, wherein refractive power required for conjugating the exit pupil to the field plane is shifted to the first optical unit and/or the second optical unit.

11. An illumination system for a microlithographic projection exposure apparatus, comprising:
a) a light source,
b) an optical unit having an exit pupil,
c) a first optical raster element positioned in a plane behind the optical unit in a converging path of rays,
d) a second optical raster element % positioned in or in close proximity to an exit pupil of the optical unit,
the wherein an interspace formed between the first optical raster element and the second optical raster element is free of optical elements having refractive power.

12. The illumination system of claim 11, wherein refractive power required for conjugating the plane to the exit pupil is shifted to the first optical unit and/or an optical unit positioned behind the second optical raster element.

13. A projection exposure apparatus comprising an illumination system according to claim 1.

14. A microlithographic method of fabricating a microstructured device, comprising the following steps:
a) providing a substrate supporting a light sensitive layer;
b) providing a reticle containing structures to be imaged onto the light sensitive layer;
c) providing an illumination system according to claim 1;
d) projecting at least a part of the reticle onto the light sensitive layer by means of a projection lens.

15. (canceled)

16. A projection exposure apparatus comprising an illumination system according to claim 9.

17. A projection exposure apparatus comprising an illumination system according to claim 11.

18. A microlithographic method of fabricating a microstructured device, comprising the following steps:
a) providing a substrate supporting a light sensitive layer;
b) providing a reticle containing structures to be imaged onto the light sensitive layer;
c) providing an illumination system according to claim 9;
d) projecting at least a part of the reticle onto the light sensitive layer by means of a projection lens.

19. A microlithographic method of fabricating a microstructured device, comprising the following steps:
a) providing a substrate supporting a light sensitive layer;
b) providing a reticle containing structures to be imaged onto the light sensitive layer;
c) providing an illumination system according to claim 11;
d) projecting at least a part of the reticle onto the light sensitive layer by means of a projection lens.
